(19) United States
(12) Patent Application Publication
(10) Pub. No.: US 2022/0336711 A1
(43) Pub. Date: Oct. 20, 2022

(54) LIGHT-EMITTING ELEMENT AND DISPLAY DEVICE INCLUDING THE SAME

(71) Applicants: Samsung Display Co., LTD., Yongin-si (KR); POSTECH Research and Business Development Foundation, Pohang-si (KR)

(72) Inventors: Se Young KIM, Hwaseong-si (KR); Jong Lam LEE, Pohang-si (KR); Won Seok CHO, Pohang-si (KR); Dong Uk KIM, Hwaseong-si (KR); Jae Yong PARK, Pohang-si (KR); Chul Jong YOO, Seongnam-si (KR)

(73) Assignees: Samsung Display Co., LTD., Yongin-si (KR); POSTECH Research and Business Development Foundation, Pohang-si (KR)

(21) Appl. No.: 17/694,889

(22) Filed: Mar. 15, 2022

(30) Foreign Application Priority Data
Apr. 19, 2021 (KR) 10-2021-0050377

(51) Int. Cl. H01L 33/38; H01L 33/42

(52) U.S. Cl. CPC H01L 33/382; H01L 33/42

(57) ABSTRACT

A light-emitting element and a display device including the same are provided. The light-emitting element comprises a first semiconductor layer doped with an n-type dopant, a second semiconductor layer disposed below the first semiconductor layer and doped with a p-type dopant, a light-emitting layer disposed between the first semiconductor layer and the second semiconductor layer, a first intermediate layer disposed on the first semiconductor layer, and including a metal, and an electrode layer disposed on the first intermediate layer. Light from the light-emitting layer transmits through the first semiconductor layer, the first intermediate layer, and the electrode layer at a transmittance equal to or greater than about 70%.

### CROSS-REFERENCE TO RELATED APPLICATION(S)

This application claims priority to and benefits of Korean Patent Application No. 10-2021-0050377 under 35 U.S.C. §119, filed on Apr. 19, 2021 in the Korean Intellectual Property Office, the entire contents of which are incorporated herein by reference.

### BACKGROUND

### 1. Technical Field

The disclosure relates to a light-emitting element and a display device including the same.

### 2. Description of the Related Art

A display device has increasing importance as the development of multimedia continues. Within this trend, various types of display devices such as an organic light-emitting display device (OLED), a liquid crystal display device (LCD), etc. have been used.

A display device has a display panel such as an organic light-emitting display panel or a liquid crystal display panel. The light-emitting display panel may include a light-emitting element. For example, a light-emitting diode (LED) as the light-emitting element may include an organic light-emitting diode OLED using an organic material as a light-emitting material and an inorganic light-emitting diode using an inorganic material as the light-emitting material.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element that may have improved electrical characteristics and transparency, and a display device including the same.

The disclosure is not limited to the above-mentioned purpose. Other features and advantages according to the disclosure that are not mentioned may be understood based on following descriptions, and may be more clearly understood based on embodiments according to the disclosure. It will be easily understood that the features and advantages according to the disclosure may be realized using elements shown in the claims and combinations thereof.

According to an embodiment of the disclosure, a light-emitting element may include a first semiconductor layer doped with an n-type dopant, a second semiconductor layer disposed below the first semiconductor layer and doped with a p-type dopant, a light-emitting layer disposed between the first semiconductor layer and the second semiconductor layer, a first intermediate layer disposed on the first semiconductor layer, and including a metal, and an electrode layer disposed on the first intermediate layer, wherein light from the light-emitting layer transmits through the first semiconductor layer, the first intermediate layer, and the electrode layer at a transmittance equal to or greater than about 70%.

In an embodiment, the first intermediate layer may include at least one selected from a group consisting of indium (In), tin (Sn), titanium (Ti), aluminum (Al), chromium (Cr), silver (Ag), gold (Au), palladium (Pd), nickel (Ni), tungsten (W), iridium (Ir), platinum (Pt), cobalt (Co), copper (Cu), ruthenium (Ru), rhodium (Rh), rubidium (Rb), lanthanum (La), cerium (Ce), sodium (Na), and europium (Eu).

In an embodiment, the first intermediate layer may include a surface that contacts the first semiconductor layer, and an opposite surface that contacts the first intermediate layer.

In an embodiment, the first intermediate layer may have a work function that is between a work function of the first semiconductor layer and a work function of the electrode layer.

In an embodiment, a thickness of the first intermediate layer may be in a range of about 1 nm to about 30 nm.

In an embodiment, the electrode layer may include a metal oxide, and the metal oxide may include at least one selected from a group consisting of ITO (indium tin oxide), AlZO (aluminum zinc oxide), IZO (indium zinc oxide), ZnO (zinc oxide), InₓO_{y} (indium oxide), SnₓO_{y} (tin oxide), AlOₓ (aluminum oxide) and GaₓO_{y} (gallium oxide).

In an embodiment, the electrode layer and the first intermediate layer may include a same material.

In an embodiment, the n-type dopant of the first semiconductor layer may have a concentration gradient where a concentration of the n-type dopant increases toward the first intermediate layer.

In an embodiment, the light-emitting element may further include a second intermediate layer disposed between the first semiconductor layer and the first intermediate layer, wherein the second intermediate layer may include a surface that contacts the first semiconductor layer, and an opposite surface that contacts the first intermediate layer.

In an embodiment, the second intermediate layer may include a metal nitride, and a metal of the metal nitride may include at least one selected from a group consisting of indium (In), tin (Sn), titanium (Ti), aluminum (Al), chromium (Cr), silver (Ag), gold (Au), palladium (Pd), nickel (Ni), tungsten (W), iridium (Ir), platinum (Pt), cobalt (Co), copper (Cu), ruthenium (Ru), rhodium (Rh), rubidium (Rb), lanthanum (La), cerium (Ce), sodium (Na), and europium (Eu).

In an embodiment, a contact resistivity of the light-emitting device may be equal to or less than about 10⁻³ Ωcm².

In an embodiment, the light emitting element may further include an insulating film that surrounds the first semiconductor layer, the second semiconductor layer, the light-emitting layer, the first intermediate layer, and the electrode layer.

According to an embodiment of the disclosure, a display device may include a first electrode and a second electrode each disposed on a substrate and spaced apart from each other, a first insulating layer disposed on the first electrode and the second electrode, light-emitting elements disposed on the first insulating layer and vertically overlapping the first electrode and the second electrode, a first connection electrode that contacts an end of each light-emitting elements, and a second connection electrode that contacts an opposite end of each light-emitting elements. Each of the light-emitting elements may include a first semiconductor layer doped with an n-type dopant, a second semiconductor layer disposed below the first semiconductor layer and doped with a p-type dopant, a light-emitting layer disposed between the first semiconductor layer and the second semiconductor layer, a first intermediate layer disposed on the first semiconductor layer, and including a metal, and an electrode layer disposed on the first intermediate layer. Light from the light-emitting layer may transmit through the first semiconductor layer, the first intermediate layer, and the electrode layer at a transmittance equal to or greater than about 70%, the second semiconductor layer may contact the first connection electrode, and the electrode layer may contact the second connection electrode.

In an embodiment, a thickness of the first intermediate layer may be in a range of about 1 nm to about 30 nm.

In an embodiment, the first intermediate layer may include a surface that contacts the first semiconductor layer, and an opposite surface that contacts the first intermediate layer.

In an embodiment, the first intermediate layer may have a work function that is between a work function of the first semiconductor layer and a work function of the electrode layer.

In an embodiment, the n-type dopant of the first semiconductor layer may have a concentration gradient in which a concentration of the n-type dopant increases toward the first intermediate layer.

In an embodiment, each light-emitting element may further include a second intermediate layer disposed between the first semiconductor layer and the first intermediate layer, the second intermediate layer may include a surface that contacts the first semiconductor layer, and an opposite surface that contacts the first intermediate layer.

In an embodiment, the second intermediate layer may include a metal nitride, and the metal nitride of the second intermediate layer and the first intermediate layer may include a same metal.

In an embodiment, a contact resistivity of each light-emitting element may be equal to or less than about 10⁻³ Ωcm².

In the light-emitting element according to the embodiments and the display device including the same, the electrode layer including the metal oxide may be formed as one end of the light-emitting element, thereby improving contact characteristic of the element with the connection electrode of the display device.

The first intermediate layer may be formed between the first semiconductor layer and the electrode layer, thereby creating an ohmic contact between the first semiconductor layer and the electrode layer. Accordingly, contact resistivity between the first semiconductor layer and the first electrode layer in the light-emitting element may be reduced, such that a driving current of the device may be uniformly applied thereto.

The first intermediate layer may be formed to a thickness that allows light from the light-emitting layer to pass through the first intermediate layer. The electrode layer may be formed as a transparent and conductive layer. Thus, light from the light-emitting layer may emit to one end of the light-emitting element, thereby improving light extraction efficiency.

Effects of the disclosure are not limited to the above-mentioned effects, and other effects as not mentioned will be clearly understood by those skilled in the art from following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic plan view showing a pixel of a display device according to an embodiment;

FIG. 3 is a schematic cross-sectional view taken along a line N1-N1′ in FIG. 2;

FIG. 4 is a schematic cross-sectional view taken along a N2-N2′ line in FIG. 2;

FIG. 5 is a schematic diagram of a light-emitting element according to an embodiment;

FIG. 6 is a schematic cross-sectional view of the light-emitting element of FIG. 5;

FIG. 7 is an energy band diagram illustrating a work function of each of a connection electrode and a first semiconductor layer;

FIG. 8 is an energy band diagram illustrating a work function of each of a connection electrode, a first intermediate layer, and a first semiconductor layer;

FIG. 9 is a schematic cross-sectional view showing a light-emitting element according to an embodiment;

FIG. 10 is a schematic cross-sectional view showing a light-emitting element according to an embodiment;

FIG. 11 is a schematic cross-sectional view showing a light-emitting element according to an embodiment;

FIG. 12 is a graph showing a current based on an operation voltage of a light-emitting element sample #3 according to Experimental Example 1;

FIG. 13 is a graph showing a current based on an operation voltage of a light-emitting element sample #4 according to Experimental Example 1;

FIG. 14 is a graph showing a contact resistivity based on a heat-treatment temperature of each of light-emitting element samples #1, #2, #3 and #4 according to Experimental Example 1;

FIG. 15 is a graph showing a current based on an operation voltage of a light-emitting element sample #5 according to Experimental Example 2;

FIG. 16 is a graph showing a current based on an operation voltage of a light-emitting element sample #6 according to Experimental Example 2;

FIG. 17 is a graph showing a contact resistivity based on a heat-treatment temperature of each of light-emitting element samples #1, #2, #5 and #6 according to Experimental Example 2;

FIG. 18 is a graph showing a current based on an operation voltage of a light-emitting element sample #7 according to Experimental Example 3;

FIG. 19 is a graph showing a current based on an operation voltage of a light-emitting element sample #8 according to Experimental Example 3;

FIG. 20 is a graph showing a contact resistivity based on a heat-treatment temperature of each of light-emitting element samples #1, #2, #7 and #8 according to Experimental Example 3;

FIG. 21 is a graph showing a transmittance based on a thickness of a first intermediate layer made of titanium and a thickness of an electrode layer made of ITO;

FIG. 22 is a graph showing a transmittance based on a thickness of the first intermediate layer of indium and the thickness of the electrode layer made of ITO;

FIG. 23 is a graph showing a transmittance based on a thickness of a first intermediate layer made of tin and a thickness of an electrode layer made of ITO; and

FIG. 24 is a graph showing an average transmittance of each of substrate samples based on a heat-treatment temperature according to Experimental Example 4.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

It will be understood that the terms “connected to” or “coupled to” may include a physical or electrical connection or coupling.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

Each of the features of the various embodiments of the disclosure may be combined with each other, in part or in whole, and technically various interlocking and driving are possible. Each embodiment may be implemented independently of each other or may be implemented together in an association.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

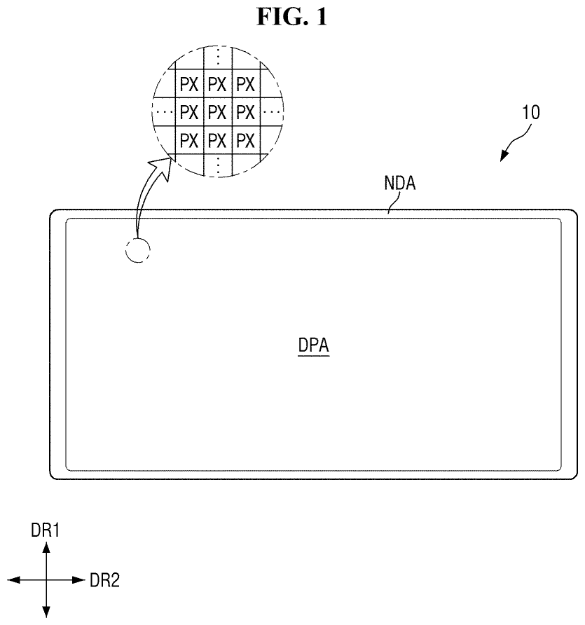

FIG. 1 is a schematic plan view of a display device according to an embodiment.

Referring to FIG. 1, a display device 10 displays a video or a still image. The display device 10 may refer to any electronic device that provides a display screen. For example, the display device 10 may include a television, a laptop, a monitor, a billboard, an Internet of Thing, a mobile phone, a smart phone, a tablet PC (personal computer), an electronic watch, a smart watch, a watch phone, a head mounted display (HMD), a mobile communication terminal, an electronic notebook, an e-book, a PMP (Portable Multimedia Player), a navigation device, a game device, a digital camera, a camcorder, etc. which may provide a display screen.

The display device 10 may include a display panel that provides a display screen. Examples of the display panel may include an inorganic light-emitting diode display panel, an organic light-emitting display panel, a quantum dot light-emitting display panel, a plasma display panel, and a field emission display panel. Hereinafter, an example in which an inorganic light-emitting diode display panel is embodied as the display panel will be described. However, the disclosure is not limited thereto. When the same technical idea is applicable to other display panels, the disclosure may also be applied to the other display panels.

A shape of the display device 10 may be variously modified. For example, the display device 10 may have a shape such as a vertically long rectangular shape, a horizontally long rectangular shape, a square, a rectangular shape with rounded corners, other polygons, or a circle. A shape of a display area DPA of the display device 10 may also be similar to a general shape of the display device 10. In FIG. 1, an embodiment of the display device 10 having a rectangular shape with an elongate length in a second direction DR2 is illustrated. The display device 10 may include the display area DPA and a non-display area NDA. The display area DPA refers to an area where a screen may be displayed, while the non-display area NDA refers to an area where the screen is not displayed. The display area DPA may be referred to as an active area, and the non-display area NDA may be referred to as a non-active area. The display area DPA may generally occupy an inner region of the display device 10.

The display area DPA may include pixels PX. The pixels PX may be arranged in a matrix form. A shape of each pixel PX may be rectangular or square in a plan view, but is not limited thereto. The shape thereof may be a rhombus shape in which each side is inclined relative to one direction. The pixels PX may be arranged in a stripe configuration or a PENTILE™ configuration. Each of the pixel PX may include one or more light-emitting elements emitting light of a specific wavelength band to display a specific color.

The non-display area NDA may be disposed around the display area DPA. The non-display area NDA may completely or partially surround the display area DPA. The display area DPA may have a rectangular shape, while each non-display area NDA may be disposed adjacent to each of four sides of the display area DPA. The non-display area NDA may constitute a bezel of the display device 10. Lines or circuit drivers included in the display device 10 may be disposed in each non-display area NDA. External devices may be mounted in the non-display area NDA.

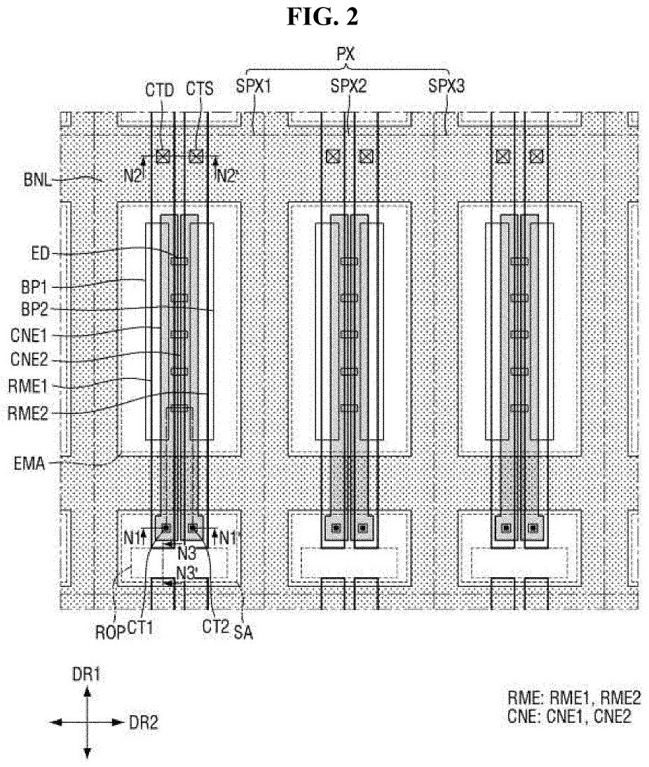

FIG. 2 is a schematic plan view showing a pixel of a display device according to an embodiment.

Referring to FIG. 2, each of the pixels PX of the display device 10 may include sub-pixels SPXn, where n may be 1 to 3. For example, a pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. For example, the first color may be blue, the second color may be green, and the third color may be red. However, the disclosure is not limited thereto. The sub-pixels SPXn may emit light of a same color. In an embodiment, each of the sub-pixels SPXn may emit blue light. In FIG. 2, it is illustrated that a pixel PX includes three sub-pixels SPXn. However, the disclosure is not limited thereto. A single pixel PX may include a larger number of sub-pixel SPXn.

Each of the sub-pixels SPXn of the display device 10 may include a light-emitting area EMA and a non-light emitting area. The light-emitting area EMA may refer to an area in which a light-emitting element ED is disposed such that light of a specific wavelength band is emitted. The non-light emitting area may refer to an area in which the light-emitting element ED is not disposed and which light from the light-emitting element ED does not reach, and in which light is not emitted.

The light-emitting area may include an area in which the light-emitting element ED is disposed, and an area adjacent to the light-emitting element ED to which light from the light-emitting element ED is emitted. However, the disclosure is limited thereto. The light-emitting area EMA may include an area to which light from the light-emitting element ED is reflected or refracted from another member and is directed. Light-emitting elements ED may be arranged in each sub-pixel SPXn. An area in which the light-emitting elements ED are disposed and an area adjacent thereto may constitute the light-emitting area EMA.

Although the drawing illustrates that light-emitting areas EMA of the sub-pixels SPXn have a uniform area size, the disclosure is not limited thereto. In embodiments, each light-emitting area EMA of each sub-pixel SPXn may have an area size that varies based on a color or a wavelength band of light from a light-emitting element ED disposed in each sub-pixel.

Each sub-pixel SPXn may further include a sub-area SA disposed in the non-light emitting area. The sub-area SA may be disposed on a side in the first direction DR1 of the light-emitting area EMA, and may be disposed between light-emitting areas EMA of sub-pixels SPXn neighboring in the first direction DR1. For example, the light-emitting areas EMA may be repeatedly arranged in the second direction DR2, and the sub-areas SA may be repeatedly arranged in the second direction DR2. The light-emitting areas EMA and the sub-areas SA may be alternately arranged with each other in the first direction DR1. However, the disclosure is not limited thereto. An arrangement of the light-emitting areas EMA and the sub-areas SA in the pixels PX may be different from the arrangement of FIG. 2.

A bank layer BNL may be disposed between each of the sub-area SA and each of the light-emitting areas EMA, while a spacing therebetween may vary based on a width of the bank layer BNL. The light-emitting element ED may not be disposed in the sub-area SA in which no light emits. However, a portion of an electrode RME disposed in each sub-pixel SPXn may be disposed in the sub-area SA. Electrodes RME respectively disposed in different sub-pixels SPXn may be separated from each other via a separation portion ROP of the sub-area SA.

The bank layer BNL may include portions respectively extending in the first direction DR1 and the second direction DR2 in a plan view and thus may have a grid pattern across an entirety of the display area DPA. The bank layer BNL may extend in and along a boundary between neighboring sub-pixels SPXn to distinguish the neighboring sub-pixels SPXn from each other. The bank layer BNL may be disposed to surround each light-emitting area EMA disposed in each sub-pixel SPXn to define each light-emitting area EMA.

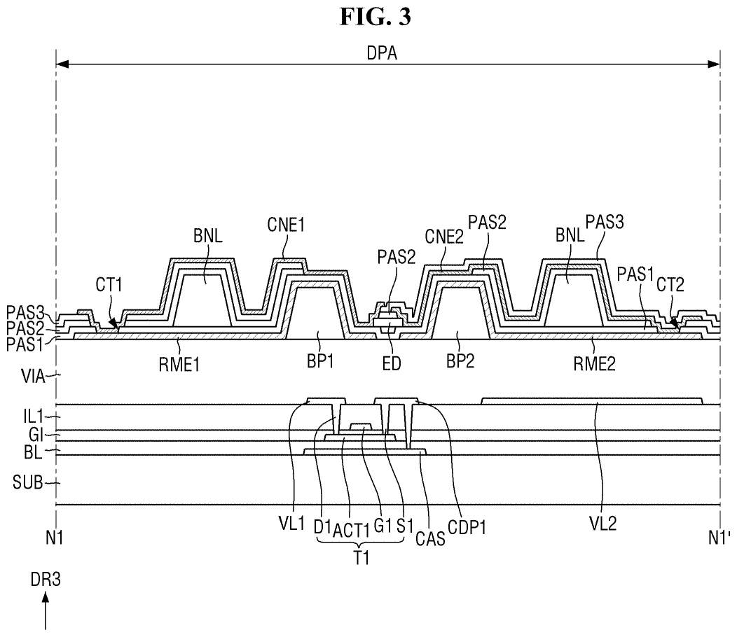

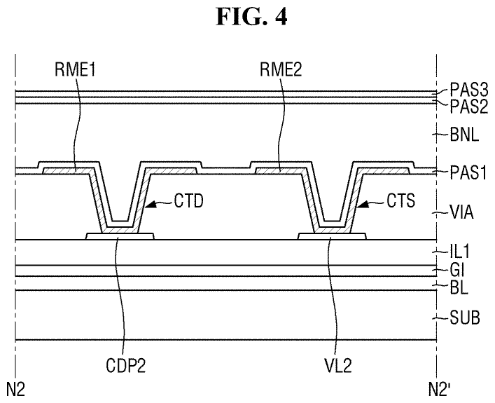

FIG. 3 is a schematic cross-sectional view taken along a line N1-N1′ in FIG. 2. FIG. 4 is a schematic cross-sectional view taken along a N2-N2′ line in FIG. 2. FIG. 3 shows a cross section of the light-emitting element ED disposed in the first sub-pixel SPX1, and FIG. 4 shows a cross section of contact holes CTD and CTS.

Referring to FIG. 2 to FIG. 4, the display device 10 may include a substrate SUB, and a semiconductor layer, conductive layers, and insulating layers disposed on the substrate SUB. The semiconductor layer, the conductive layers, and the insulating layers may constitute each of a circuit layer and a display element layer of the display device 10.

For example, the substrate SUB may be an insulating substrate. The substrate SUB may be made of an insulating material such as glass, quartz, or polymer resin. The substrate SUB may be a rigid substrate, or may be a flexible substrate capable of bending, folding, rolling, etc.

A first conductive layer may be disposed on the substrate SUB. The first conductive layer may include a lower metal layer CAS, and the lower metal layer CAS may be disposed to overlap an active layer ACT1 of a first transistor T1. The lower metal layer CAS includes a material that blocks light to prevent light from being incident into the active layer ACT1 of the first transistor. However, the lower metal layer CAS may be omitted.

A buffer layer BL may be disposed on the lower metal layer CAS and the substrate SUB. The buffer layer BL may be formed on the substrate SUB to protect transistors of the pixel PX from moisture invading through the substrate SUB which may be vulnerable to moisture permeation. The buffer layer BL may provide a surface planarization function.

The semiconductor layer may be disposed on the buffer layer BL. The semiconductor layer may include the active layer ACT1 of the first transistor T1. The active layer ACT1 may be disposed to partially overlap a gate electrode G1 of a second conductive layer to be described later.

The semiconductor layer may include polycrystalline silicon, monocrystalline silicon, oxide semiconductor, and the like. In an embodiment, the semiconductor layer may include polycrystalline silicon. The oxide semiconductor may be an oxide semiconductor containing indium (In). For example, the oxide semiconductor may include at least one selected from a group consisting of indium tin oxide (ITO), indium zinc oxide (IZO), indium gallium oxide (IGO), indium zinc tin oxide (IZTO), indium gallium tin oxide (IGTO), indium gallium zinc oxide (IGZO), indium gallium zinc tin oxide (IGZTO).

Although the drawing illustrates that a single first transistor T1 is disposed in the sub-pixel SPXn of the display device 10, the disclosure is not limited thereto. The display device 10 may include a larger number of transistors.

A first gate insulating layer GI may be disposed on the semiconductor layer and the buffer layer BL. The first gate insulating layer GI may serve as a gate insulating film of the first transistor T1.

The second conductive layer may be disposed on the first gate insulating layer GI. The second conductive layer may include a gate electrode G1 of the first transistor T1. The gate electrode G1 may be disposed to overlap a channel area of the active layer ACT1 in a third direction DR3 as a thickness direction of the element.

A first interlayer insulating layer IL1 may be disposed on the second conductive layer. The first interlayer insulating layer IL1 may function as an insulating film between the second conductive layer and other layers disposed thereon and may protect the second conductive layer.

A third conductive layer may be disposed on the first interlayer insulating layer ILL The third conductive layer may include a first voltage line VL1 and a second voltage line VL2, and conductive patterns CDP1 and CDP2 disposed in the display area DPA.

A high-potential voltage (or a first power voltage) transmitted to a first electrode RME1 may be applied to the first voltage line VL1, while a low-potential voltage (or a second power voltage) transmitted to a second electrode RME2 may be applied to the second voltage line VL2. A portion of the first voltage line VL1 may contact the active layer ACT1 of the first transistor T1 via a contact hole extending through the first interlayer insulating layer IL1 and the first gate insulating layer GI. The first voltage line VL1 may serve as a first drain electrode D1 of the first transistor T1. The second voltage line VL2 may be directly connected to the second electrode RME2 to be described later.

A first conductive pattern CDP1 may contact the active layer ACT1 of the first transistor T1 via a contact hole extending through the first interlayer insulating layer IL1 and the first gate insulating layer GI. The first conductive pattern CDP1 may contact the lower metal layer CAS via another contact hole. The first conductive pattern CDP1 may serve as a first source electrode Si of the first transistor T1.

A second conductive pattern CDP2 may be connected to the first electrode RME1 to be described later. The second conductive pattern CDP2 may be electrically connected to the first transistor T1 via the first conductive pattern CDP1. In the drawing, it is illustrated that the first conductive pattern CDP1 and the second conductive pattern CDP2 are separated from each other. However, the disclosure is not limited thereto. In embodiments, the second conductive pattern CDP2 may be integrated with the first conductive pattern CDP1 to form a single pattern. The first transistor T1 may transfer the first power voltage applied from the first voltage line VL1 to the first electrode RME1.

The drawing illustrates that the first conductive pattern CDP1 and the second conductive pattern CDP2 constitute a same layer. However, the disclosure is not limited thereto. In embodiments, the second conductive pattern CDP2 and the first conductive pattern CDP1 may constitute different conductive layers. For example, the second conductive pattern CDP2 and the first conductive pattern CDP1 may respectively constitute a third conductive layer, and a fourth conductive layer disposed on a third conductive layer while some insulating layers are interposed therebetween. The first voltage line VL1 and the second voltage line VL2 may constitute the fourth conductive layer rather than the third conductive layer. The first voltage line VL1 may be electrically connected to the drain electrode D1 of the first transistor T1 via another conductive pattern.

Each of the buffer layer BL, the first gate insulating layer GI, and the first interlayer insulating layer IL1 as above-described may be composed of a stack of inorganic layers. For example, each of the buffer layer BL, the first gate insulating layer GI, and the first interlayer insulating layer IL1 may be composed of a stack of double inorganic layers made of at least one of silicon oxide (SiOₓ), silicon nitride (SiNₓ), or silicon oxynitride (SiOₓN_{y}), or be composed of a stack of multiple layers made thereof which are alternately stacked one on top of another. However, the disclosure is not limited thereto. Each of the buffer layer BL, the first gate insulating layer GI, and the first interlayer insulating layer IL1 may be composed of a single inorganic layer including the above-described insulating material. In embodiments, the first interlayer insulating layer IL1 may be made of an organic insulating material such as polyimide (PI).

Each of the second conductive layer and the third conductive layer may be composed of a single layer or multiple layers made of one of molybdenum (Mo), aluminum (Al), chromium (Cr), gold (Au), titanium (Ti), nickel (Ni), neodymium (Nd), copper (Cu), or an alloy thereof. However, the disclosure is not limited thereto.

A via layer VIA may be disposed on the third conductive layer. The via layer VIA may include an organic insulating material such as polyimide (PI) and may provide a surface planarization function.

A display element layer may be disposed on the via layer VIA. The display element layer may include bank patterns BP1 and BP2, electrodes RME (RME1 and RME2), a bank layer BNL, light-emitting elements ED, and connection electrodes CNE (CNE1 and CNE2). Insulating layers PAS1, PAS2, and PAS3 may be disposed on the via layer VIA.

The bank patterns BP1 and BP2 may be directly disposed on the via layer VIA. The bank patterns BP1 and BP2 may have a shape extending in the first direction DR1 and may be spaced apart from each other in the second direction DR2. For example, the bank patterns BP1 and BP2 may include a first bank pattern BP1 and a second bank pattern BP2 spaced apart from each other and disposed in the light-emitting area EMA of each sub-pixel SPXn. The first bank pattern BP1 may be disposed at a left side in the second direction DR2 around a center of the light-emitting area EMA, while the second bank pattern BP2 may be disposed at a right side in the second direction DR2 around the center of the light-emitting area EMA. The light-emitting elements ED may be disposed between the first bank pattern BP1 and the second bank pattern BP2.

Each of the bank patterns BP1 and BP2 may have a length extending in the first direction DR1 which may be smaller than a length in the first direction DR1 of the light-emitting area EMA surrounded with the bank layer BNL. The bank patterns BP1 and BP2 may be disposed in the light-emitting area EMA of the sub-pixel SPXn and in an entirety of the display area DPA and may have an island-like shape having a narrow width and extending in one direction. In the drawing, it is illustrated that two bank patterns BP1 and BP2 having a same width are disposed in each sub-pixel SPXn. However, the disclosure is not limited thereto. The number and a shape of the bank patterns BP1 and BP2 may vary depending on the number or an arrangement structure of the electrodes RME.

Each of the bank patterns BP1 and BP2 may have a structure in which at least a portion thereof protrudes from a top surface of the via layer VIA. The protruding portion of each of the bank patterns BP1 and BP2 may have an inclined side surface. The light from the light-emitting element ED may be reflected from the electrodes RME disposed on the bank patterns BP1 and BP2 and emitted upwardly from the via layer VIA. However, the disclosure is not limited thereto. Each of the bank patterns BP1 and BP2 may have a semi-circle or semi-ellipse shape with a curved outer surface. Each of the bank patterns BP1 and BP2 may include an organic insulating material such as polyimide (PI). However, the disclosure is not limited thereto.

Each of the electrodes RME may have a shape extending in one direction and the electrodes RME may be disposed in each sub-pixel SPXn. Each of the electrodes RME may extend in the first direction DR1. The electrodes RME may be disposed in the light-emitting area EMA of the sub-pixel SPXn and may be spaced apart from each other in the second direction DR2. The electrodes RME may be electrically connected to the light-emitting element ED. Each electrode RME may be connected to the light-emitting element ED via the connection electrode CNE (CNE1 and CNE2) which will be described later and may transmit an electrical signal applied from the underlying conductive layer to the light-emitting element ED.

The display device 10 may include the first electrode RME1 and the second electrode RME2 disposed in each sub-pixel SPXn. The first electrode RME1 may be disposed at a left side around the center of the light-emitting area EMA. The second electrode RME2 may be spaced apart from the first electrode RME1. The second direction DR2 may be disposed at a right side around the center of the light-emitting area EMA. The first electrode RME1 may be disposed on the first bank pattern BPI, and the second electrode RME2 may be disposed on the second bank pattern BP2. Each of the first electrode RME1 and the second electrode RME2 may extend beyond the bank layer BNL and be partially disposed in a corresponding sub-pixel SPXn and the sub-area SA thereof. The first electrode RME1 and the second electrode RME2 of a sub-pixel SPXn may be respectively spaced apart from the first electrode RME1 and the second electrode RME2 of another sub-pixel SPXn adjacent thereto via the separation portion ROP located in the sub-area SA of a sub-pixel SPXn.

The first electrode RME1 and the second electrode RME2 may be respectively disposed at least on the inclined side surfaces of the bank patterns BP1 and BP2. In an embodiment, a width measured in the second direction DR2 of each of the electrodes RME may be smaller than a width measured in the second direction DR2 of each of the bank patterns BP1 and BP2. Each of the first electrode RME1 and the second electrode RME2 may be disposed to cover at least one side surface of each of the bank patterns BP1 and BP2, so that light from the light-emitting element ED may be reflected therefrom.

A spacing between the first electrode RME1 and the second electrode RME2 in the second direction DR2 may be smaller than a spacing between the bank patterns BP1 and BP2 in the second direction DR2. At least a partial area of each of the first electrode RME1 and the second electrode RME2 may be directly disposed on the via layer VIA and thus may be disposed on a same plane.

As described above, each of the electrodes RME may be disposed on each of the bank patterns BP1 and BP2. Light from the light-emitting elements ED disposed between the bank patterns BP1 and BP2 may be reflected from the electrodes RME disposed on the bank patterns BP1 and BP2 and may be emitted in an upward direction. Each electrode RME may include a highly reflective conductive material and may thus reflect light from the light-emitting element ED.

Each electrode RME may extend from the light-emitting area EMA to the sub-area SA, and may include a portion overlapping the bank layer BNL, and a portion disposed in the sub-area SA. According to an embodiment, a portion of each electrode RME which includes an exposed top surface may be disposed in the sub-area SA. However, the disclosure is not limited thereto. A portion of each electrode RME which includes an exposed top surface may be disposed in the light-emitting area EMA.

Each of the first electrode RME1 and the second electrode RME2 may be connected to the third conductive layer via each of a first contact hole CTD and a second contact hole CTS formed in the via layer VIA and in each of first and second areas overlapping the bank layer BNL. The first electrode RME1 may contact the second electrode pattern CDP2 via the first contact hole CTD extending through the underlying via layer VIA. The second electrode RME2 may contact the second voltage line VL2 via the second contact hole CTS extending through the underlying via layer VIA. The first electrode RME1 may be electrically connected to the first transistor T1 via the second electrode pattern CDP2 and the first electrode pattern CDP1 so that the first power voltage may be applied to the first electrode RME1. The second electrode RME2 may be electrically connected to the second voltage line VL2 so that the second power voltage may be applied to the second electrode RME2.

A first insulating layer PAS1 may be disposed over an entirety of the display area DPA, and may be disposed on the via layer VIA and the electrodes RME. The first insulating layer PAS1 may protect the electrodes RME and at the same time, insulate the different electrodes RME from each other. For example, the first insulating layer PAS1 may be disposed to cover the electrodes RME before the bank layer BNL is formed. This may prevent the electrodes RME from being damaged in a process of forming the bank layer BNL. The first insulating layer PAS1 may prevent the light-emitting element ED disposed thereon from being damaged due to direct contact of the element ED with other members.

In an embodiment, the first insulating layer PAS1 may have a step so that a portion of a top surface thereof is depressed in an area between adjacent electrodes RME spaced apart from each other in the second direction DR2. The light-emitting element ED may be disposed on a portion of a top surface of the first insulating layer PAS1 where the step is formed. A space may be formed between the light-emitting element ED and the first insulating layer PAS1.

According to an embodiment, the first insulating layer PAS1 may be disposed to cover the electrodes RME, and may have openings defined therein, each opening exposing a portion of a top surface of the electrodes RME. For example, the first insulating layer PAS1 may include first and second contacts CT1 and CT2 respectively exposing portions of the top surfaces of the first and second electrodes RME1 and RME2. The first contact CT1 may be disposed on the first electrode RME1 and in the sub-area SA, and the second contact CT2 may be disposed on the second electrode RME2 and in the sub-area SA. The connection electrodes CNE to be described later may respectively contact the exposed portions of the first and second electrodes RME1 and RME2 via the first contact CT1 and the second contact CT2. The first insulating layer PAS1 may expose a portion of a top surface of the via layer VIA in an area corresponding to the separation portion ROP via which the electrodes RME of different sub-pixels SPXn are spaced apart from each other.

The bank layer BNL may be disposed on the first insulating layer PAS1. The bank layer BNL includes a portion extending in the first direction DR1 and a portion extending in the second direction DR2, and may surround each sub-pixel SPXn. The bank layer BNL may surround each of the light-emitting area EMA and the sub-area SA of each sub-pixel SPXn and thus may distinguish the light-emitting area EMA and the sub-area SA from each other. The bank layer BNL may surround the outermost portion of the display area DPA, and thus may distinguish the display area DPA and the non-display area NDA from each other. The bank layer BNL may be disposed over an entirety of the display area DPA and have a grid pattern. Portions of the display area DPA exposed through the bank layer BNL may respectively act as the light-emitting area EMA and the sub-area SA.

The bank layer BNL may have a vertical dimension as each of the bank patterns BP1 and BP2 may have a vertical dimension. In embodiments, a vertical level of a top surface of the bank layer BNL may be higher than that of each of the bank patterns BP1 and BP2, and a thickness of the bank layer may be equal to or greater than each of the bank patterns BP1 and BP2. The bank layer BNL may prevent ink from overflowing to an adjacent sub-pixel SPXn in an inkjet printing process during a display device manufacturing process. Each of the bank patterns BP1 and BP2 and the bank layer BNL may include an organic insulating material such as polyimide.

The light-emitting elements ED may be disposed on the first insulating layer PAS1. The light-emitting element ED may have a shape extending in one direction which may be parallel to a plane of the substrate SUB. As will be described later, the light-emitting element ED may include semiconductor layers arranged along the extending direction of the light-emitting element ED. The semiconductor layers may be sequentially arranged along a direction parallel to a top surface of the substrate SUB. However, the disclosure is not limited thereto. When the light-emitting element ED has a different structure, the semiconductor layers may be arranged in a direction perpendicular to the top surface of the substrate SUB.

The light-emitting elements ED may be disposed on the electrodes RME spaced apart from each other in the second direction DR2 and may be disposed between the bank patterns BP1 and BP2.

The light-emitting element ED may have a length in the second direction DR2 greater than a spacing between the electrodes RME spaced apart from each other in the second direction DR2. At least one end of each of the light-emitting elements ED may be disposed on one of the electrodes RME, or opposing ends of the light-emitting elements ED may each be disposed on different electrodes RME, respectively. A direction in which each electrode RME extends and a direction in which the light-emitting element ED extends may be substantially perpendicular to each other. The light-emitting elements ED may be spaced apart from each other along the first direction DR1 in which each electrode RME extends. The light-emitting elements ED may be aligned with each other in substantially a parallel manner to each other. However, the disclosure is not limited thereto. The light-emitting element ED may obliquely extend in a direction in which each electrode RME extends.

The light-emitting elements ED disposed in each sub-pixel SPXn may respectively emit light of different wavelength bands according to types of materials of the above-described semiconductor layers thereof. However, the disclosure is not limited thereto. The light-emitting elements ED disposed in each sub-pixel SPXn may respectively include semiconductor layers made of a same material, and thus emit light of a same color. Each of the light-emitting elements ED may contact the connection electrodes CNE (CNE1 and CNE2), and thus be electrically connected to the electrodes RME and the conductive layers below the via layer VIA. Thus, an electrical signal may be applied to each light-emitting element ED to emit light of a specific wavelength band.

The light-emitting element ED may include semiconductor layers respectively doped with dopants having different types of conductivity. Current may be transmitted to the light-emitting element ED via the connection electrode CNE in contact with the semiconductor layers so that light may emit from the element ED. When the connection electrode CNE is composed of a transparent conductive layer through which light may pass, for example ITO, an ohmic contact between the connection electrode CNE and the semiconductor layer may not be achieved, such that the driving current may not be uniformly applied thereto.

According to an embodiment, the light-emitting element ED may include a first intermediate layer and an electrode layer, to allow an ohmic contact between the semiconductor layer and the connection electrode CNE. Thus, ohmic contact may be achieved between the semiconductor layer, the first intermediate layer, and the electrode layer, so that a driving current may be uniformly applied to the light-emitting element ED. A detailed description thereof will be made later.

A second insulating layer PAS2 may be disposed on the light-emitting elements ED, the first insulating layer PAS1, and the bank layer BNL. The second insulating layer PAS2 may include a pattern which may extend in the first direction DR1 and between the bank patterns BP1 and BP2 and may be disposed on the light-emitting elements ED. The pattern may be disposed to partially cover an outer surface of the light-emitting element ED, and may not cover both opposing sides or both opposing ends of the light-emitting element ED. The pattern may have a linear or island-like shape in each sub-pixel SPXn in a plan view. The pattern of the second insulating layer PAS2 may protect the light-emitting element ED and at the same time, fix the light-emitting element ED in a manufacturing process of the display device 10. The second insulating layer PAS2 may fill the space between the light-emitting element ED and the underlying first insulating layer PAS1. A portion of the second insulating layer PAS2 may be disposed on the bank layer BNL and in the sub-area SA. A portion of the second insulating layer PAS2 disposed in the sub-area SA may not be disposed on the first contact CT1 and the second contact CT2, and the separation portion ROP.

The connection electrodes CNE (CNE1 and CNE2) may be disposed on and may contact the electrodes RME, and the light-emitting elements ED, respectively. The connection electrode CNE may contact at least one of the electrodes RME via an end of the light-emitting element ED and each of the contacts CT1 and CT2 extending through the first insulating layer PAS1 and the second insulating layer PAS2.

The first connection electrode CNE1 may have a shape extending in the first direction DR1 and may be disposed on the first electrode RME1. A portion of the first connection electrode CNE1 disposed on the first bank pattern BP1 may overlap the first electrode RME1 and may extend in the first direction DR1 therefrom. The first connection electrode CNE1 may extend from the light-emitting area EMA beyond the bank layer BNL and into the sub-area SA. The first connection electrode CNE1 may contact the first electrode RME1 via the first contact CT1 in the sub-area SA. The first connection electrode CNE1 may contact the light-emitting elements ED and the first electrode RME1 and thus transmit an electrical signal applied from the first transistor T1 to the light-emitting elements ED. The first connection electrode CNE1 may contact a second semiconductor layer 32 of the light-emitting element ED, which will be described later.

The second connection electrode CNE2 may have a shape extending in the first direction DR1 and may be disposed on the second electrode RME2. A portion of the second connection electrode CNE2 disposed on the second bank pattern BP2 may overlap the second electrode RME2 and extend in the first direction DR1 therefrom. The second connection electrode CNE2 may extend from the light-emitting area EMA beyond the bank layer BNL and into the sub-area SA. The second connection electrode CNE2 may contact the second electrode RME2 via the second contact CT2 in the sub-area SA. The second connection electrode CNE2 may contact the light-emitting elements ED and the second electrode RME2 and transmit an electrical signal applied from the second voltage line VL2 to the light-emitting elements ED. The second connection electrode CNE2 may contact an electrode layer 40 which will be described later.

Each of the first connection electrode CNE1 and the second connection electrode CNE2 may be composed of a transparent conductive layer through which light may pass. Each of the first connection electrode CNE1 and the second connection electrode CNE2 may include at least one selected from a group consisting of ITO (indium tin oxide), AlZO (aluminum zinc oxide), IZO (indium zinc oxide), ZnO (zinc oxide), InₓO_{y} (indium oxide), SnₓO_{y} (tin oxide), AlOₓ (aluminum oxide) and GaₓO_{y} (gallium oxide).

A third insulating layer PAS3 may be disposed on the second connection electrode CNE2 and the second insulating layer PAS2. The third insulating layer PAS3 may be disposed over an entire area of the second insulating layer PAS2 to cover the second connection electrode CNE2. The first connection electrode CNE1 may be disposed on the third insulating layer PAS3. The third insulating layer PAS3 may be disposed over an entire area of the via layer VIA except for an area where the first connection electrode CNE1 is disposed. The third insulating layer PAS3 may insulate the first connection electrode CNE1 and the second connection electrode CNE2 from each other so that the first connection electrode CNE1 does not directly contact the second connection electrode CNE2.

The third insulating layer PAS3 may be disposed over an entirety of the sub-area SA except for a portion thereof where the first contact CT1 is disposed and may cover the second contact CT2 and the separation portion ROP. Since the first connection electrode CNE1 is disposed in the first contact CT1, the third insulating layer PAS3 may expose the first contact CT1. Since the second connection electrode CNE2 is disposed in the second contact CT2, the third insulating layer PAS3 may cover the second contact CT2 and the second connection electrode CNE2. The third insulating layer PAS3 may cover the separation portion ROP and thus may directly contact a portion of the top surface of the via layer VIA which is exposed through a spacing between the electrodes RME.

Although not shown in the drawing, another insulating layer may be further disposed on the third insulating layer PAS3 and the first connection electrode CNE1. The insulating layer may protect the members disposed on the substrate SUB from an external environment.

Each of the first insulating layer PAS1, the second insulating layer PAS2, and the third insulating layer PAS3 may include an inorganic insulating material or an organic insulating material.

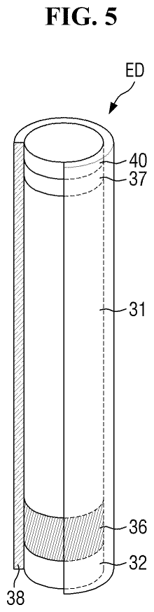

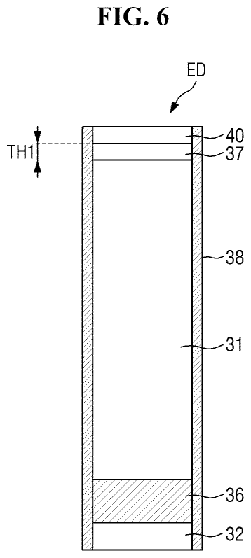

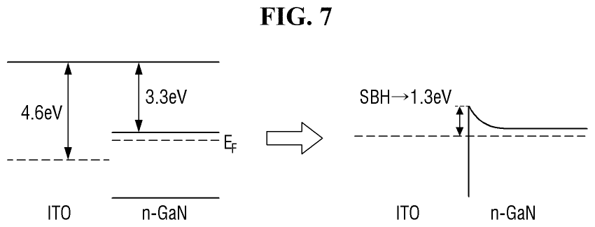

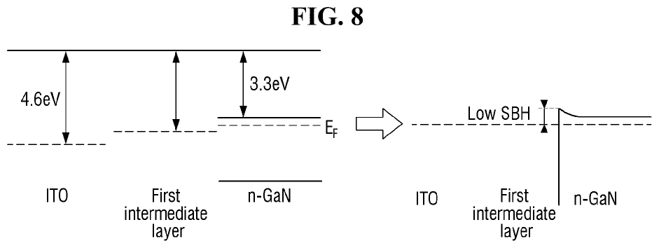

FIG. 5 is a schematic diagram of a light-emitting element according to an embodiment. FIG. 6 is a schematic cross-sectional view of the light-emitting element of FIG. 5. FIG. 6 shows a vertical cross-section of the light-emitting element ED of FIG. 5 taken along a plane through a center of the light-emitting element ED. FIG. 7 is an energy band diagram illustrating a work function of each of the connection electrode and the first semiconductor layer. FIG. 8 is an energy band diagram illustrating a work function of each of the connection electrode, the first intermediate layer, and the first semiconductor layer.

Referring to FIG. 5 and FIG. 6, the light-emitting element ED may be a light-emitting diode. For example, the light-emitting element ED may be an inorganic light-emitting diode which has a size of nano-meter to micro-meter and may be made of an inorganic material. The light-emitting element ED may be disposed between two opposing electrodes. When an electric field in a specific direction is generated between the two opposite electrodes, the light-emitting element ED may be polarized.

The light-emitting element ED according to an embodiment may have a shape extending in one direction. The light-emitting element ED may have a shape of a cylinder, a rod, a wire, a tube, etc. However, the shape of the light-emitting element ED is not limited thereto, and may have a shape of a polygonal prism such as a cube, a cuboid, or a hexagonal prism. The light-emitting element may extend in one direction and may have a partially inclined outer surface. Thus, the element ED may have various shapes.

The light-emitting element ED may include a semiconductor layer doped with any conductive type, for example, p-type or n-type impurities. The semiconductor layer may receive an electrical signal applied from an external power source and may emit light of a specific wavelength band. The light-emitting element ED may include a first semiconductor layer 31, a second semiconductor layer 32, a light-emitting layer 36, a first intermediate layer 37, the electrode layer 40, and an insulating film 38.

The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, 0≤x+y≤1). For example, the first semiconductor layer 31 may be made of at least one of AlGaInN, GaN, AlGaN, InGaN, AlN, and InN and may be doped with a n-type dopant. The n-type dopant doped into the first semiconductor layer 31 may be Si, Ge, Sn, or the like. In an embodiment, the first semiconductor layer 31 may be made of n-GaN and doped with n-type Si. A length of the first semiconductor layer 31 may be in a range of about 1.5 μm to about 5 μm. However, the disclosure is not limited thereto.

The second semiconductor layer 32 may be disposed on the first semiconductor layer 31 while the light-emitting layer 36 is interposed therebetween. The second semiconductor layer 32 may be a p-type semiconductor. The second semiconductor layer 32 may include a semiconductor material having a chemical formula of AlₓGa_{y}In_{1-x-y}N (0≤x≤1, 0≤y≤1, 0≤x+y≤1). For example, the second semiconductor layer 32 may be made of at least one of AlGaInN, GaN, AlGaN, InGaN, AlN, and InN and may be doped with a p-type dopant. The p-type dopant doped into the second semiconductor layer 32 may be Mg, Zn, Ca, Se, Ba, or the like. In an embodiment, the second semiconductor layer 32 may be made of p-GaN and may be doped with p-type Mg. A length of the second semiconductor layer 32 may be in a range of about 0.05 μm to about 0.10 μm. However, the disclosure is not limited thereto.

In an embodiment, the drawing shows that each of the first semiconductor layer 31 and the second semiconductor layer 32 is composed of a single layer. However, the disclosure is not limited thereto. Depending on a material of the light-emitting layer 36, each of the first semiconductor layer 31 and the second semiconductor layer 32 may further include a larger number of layers, for example, a cladding layer or a TSBR (tensile strain barrier reducing) layer.

The light-emitting layer 36 may be disposed between the first semiconductor layer 31 and the second semiconductor layer 32. The light-emitting layer 36 may include a material of a single or multiple quantum well structure. When the light-emitting layer 36 includes a material of a multiple quantum well structure, the light-emitting layer 36 may have a structure in which quantum layers and well layers are alternately stacked with each other. The light-emitting layer 36 may emit light via combinations between electrons and holes according to an electrical signal applied through the first semiconductor layer 31 and the second semiconductor layer 32. The light-emitting layer 36 may include a material such as AlGaN and AlGaInN. For example, when the light-emitting layer 36 has a structure in which quantum layers and well layers are alternately stacked with each other, the quantum layer may include a material such as AlGaN or AlGaInN, and the well layer may include a material such as GaN or AlInN.

The light-emitting layer 36 may have a structure in which first layers made of a semiconductor material having a larger bandgap energy and second layers made of a semiconductor material having a smaller bandgap energy are alternately stacked with each other. The light-emitting layer 36 may include Group III to Group V semiconductor materials depending on a wavelength band of emitted light. The light from the light-emitting layer 36 is not limited to light of a wavelength band corresponding to a blue color. In embodiments, the light from the light-emitting layer 36 may be light of a wavelength band corresponding to a red or green color. In an embodiment, a length of the light-emitting layer 36 may be in a range of about 0.05 μm to about 0.10 μm. However, the disclosure is not limited thereto.

The light-emitting layer 36 may emit light in a longitudinal direction of the light-emitting element ED, for example, toward opposing ends of the light-emitting element ED. In another embodiment, the light-emitting layer 36 may emit light in a direction perpendicular to a length direction of the light-emitting element ED. Directionality of light from the light-emitting layer 36 is not limited to one direction.

The light-emitting element ED may include at least one first intermediate layer 37. The first intermediate layer 37 may act as an ohmic connection electrode. The first intermediate layer 37 may be disposed between the first semiconductor layer 31 and the electrode layer 40 and may include a surface that contacts the first semiconductor layer 31 and an opposite surface that contacts the electrode layer 40. The first intermediate layer 37 may achieve an ohmic contact between the first semiconductor layer 31 and the electrode layer 40, thereby reducing contact resistivity between the first semiconductor layer 31 and the electrode layer 40 of the light-emitting element ED.

The electrode layer 40 may be disposed on a surface of the first semiconductor layer 31. The electrode layer 40 may act as one end of the light-emitting element ED. The electrode layer 40 may be a transparent conductive layer through which light from the light-emitting layer 36 may be transmitted. In an embodiment, the electrode layer 40 may be made of a same material as that of the above-described connection electrode CNE, such that a contact characteristic between the electrode layer 40 and the connection electrode CNE may be improved. The electrode layer 40 may create an ohmic contact with the first intermediate layer 37 disposed between the first semiconductor layer 31 and the electrode layer 40 in the light-emitting element ED.

The electrode layer 40 may include at least one selected from a group consisting of ITO (indium tin oxide), AlZO (aluminum zinc oxide), IZO (indium zinc oxide), ZnO (zinc oxide), InₓO_{y} (indium oxide), SnₓO_{y} (tin oxide), AlOₓ (aluminum oxide) and GaₓO_{y} (gallium oxide). The electrode layer 40 may have a single-layer or multi-layer structure.

In an embodiment, the first intermediate layer 37 may have a work function that is between a work function of the electrode layer 40 and a work function of the first semiconductor layer 31 to create ohmic contact between the electrode layer 40 and the first semiconductor layer 31. The first intermediate layer 37 may include a conductive metal.

FIG. 7 shows a difference between a work function of ITO as an example of a material of the electrode layer 40 and a work function of n-GaN as an example of a material of the first semiconductor layer 31. ITO may have a work function of about 4.6 eV, and n-GaN may have a work function of about 3.3 eV. The work function difference therebetween, which may be a Schottky barrier height (SBH), may be about 1.3 eV. For example, the Schottky barrier height between ITO and n-GaN may be large, such that ohmic contact therebetween may not be achieved and thus the Schottky contact therebetween may be achieved.

Referring to FIG. 8, when the first intermediate layer 37 has a work function that is between a work function of ITO and a work function of n-GaN, the Schottky barrier height therebetween may be smaller so that a Schottky contact therebetween may not be achieved but an ohmic contact therebetween may be achieved.

In an embodiment, the first intermediate layer 37 may have a work function between a work function of the electrode layer 40 and a work function of the first semiconductor layer 31. Thus, ohmic contact between the electrode layer 40 and the first semiconductor layer 31 may be achieved.

In an embodiment, the first intermediate layer 37 may include at least one selected from a group consisting of, for example, indium (In), tin (Sn), titanium (Ti), aluminum (Al), chromium (Cr), silver (Ag), gold (Au), palladium (Pd), nickel (Ni), tungsten (W), iridium (Ir), platinum (Pt), cobalt (Co), copper (Cu), ruthenium (Ru), rhodium (Rh), rubidium (Rb), lanthanum (La), cerium (Ce), sodium (Na), and europium (Eu). The first intermediate layer 37 may be composed of a single-layer or multi-layer structure made of at least one of the above listed materials.

The first intermediate layer 37 may have transparency so that light from the light-emitting layer 36 may transmit therethrough. In an embodiment, the first intermediate layer 37 may have a thickness TH1 in a range of about 1 nm to about 30 nm. When a thickness TH1 of the first intermediate layer 37 is equal to or greater than about 1 nm, ohmic contact may be achieved between the connection electrode CNE and the first semiconductor layer 31. When a thickness TH1 of the first intermediate layer 37 is equal to or less than about 30 nm, light may transmit through the first intermediate layer 37.

As described above, the electrode layer 40 may act as one end of the light-emitting element ED. When the electrode layer 40 contacts the connection electrode CNE of the display device 10, the contact characteristic therebetween may be excellent. Placing the first intermediate layer 37 between the first semiconductor layer 31 and the electrode layer 40 may allow ohmic contact to be achieved between the first semiconductor layer 31 and the electrode layer 40. Accordingly, contact resistivity between the electrode layer 40 and the first semiconductor layer 31 in the light-emitting element ED may be reduced, such that the driving current may be uniformly applied to the device. The first intermediate layer 37 may have a thickness that may allow the light from the light-emitting layer 36 to transmit through the first intermediate layer 37, and the electrode layer 40 may be a transparent conductive layer. Thus, light from the light-emitting layer 36 may transmit through the first intermediate layer 37 and through the electrode layer 40 to improve light extraction efficiency.

In an embodiment, in the light-emitting element ED, light from the light-emitting layer 36 may transmit through the first semiconductor layer 31, the first intermediate layer 37, and the electrode layer 40 at a transmittance equal to or greater than about 70%. Light from the light-emitting layer 36 may have a wavelength band in a range of about 400 nm to about 500 nm. An ohmic contact between the first semiconductor layer 31, the first intermediate layer 37, and the electrode layer 40 may be achieved, such that a contact resistivity of the light-emitting element ED may be equal to or less than about 10⁻³ Ωcm². In order to reduce contact resistivity between the first semiconductor layer 31, the first intermediate layer 37, and the electrode layer 40, the light-emitting element ED may be heat-treated for about several seconds to about several minutes at a temperature range of about 100 degrees C. to about 300 degrees C. However, the disclosure is not limited thereto. The heat-treatment may be omitted.

In another embodiment, a surface of the first semiconductor layer 31 of the light-emitting element ED may be surface-treated. A surface of the first semiconductor layer 31 may contact the first intermediate layer 37. The surface treatment may be performed using plasma treatment or laser irradiation. The plasma treatment may be performed using an inert gas that is not reactive with nitrogen (N), for example, using a gas such as argon (Ar), helium (He), or neon (Ne). For the laser irradiation, excitons in a 248 nm wavelength band may be used. The surface treatment such as the plasma treatment or the laser irradiation may create a nitrogen (N) defect on a surface of the first semiconductor layer 31, such that an interface characteristic between the first intermediate layer 37 and a surface of the first semiconductor layer 31 may be improved. The increase in the interface characteristic between the first semiconductor layer 31 and the first intermediate layer 37 may decrease contact resistivity between the first semiconductor layer 31 and the first intermediate layer 37.

In an embodiment, the insulating film 38 may be disposed to surround an outer surface of each of the semiconductor layers 31 and 32, the light-emitting layer 36, the first intermediate layer 37, and the electrode layer 40 as described above. For example, the insulating film 38 may be disposed to surround at least an outer surface of the light-emitting layer 36 such that opposing ends in a longitudinal direction of the light-emitting element ED may be exposed. The insulating film 38 may be formed in an area adjacent to at least one end of the light-emitting element ED so as to have a rounded top surface in a cross-sectional view.

The insulating film 38 may include a material having insulating ability, for example, silicon oxide (SiOₓ), silicon nitride (SiNₓ), silicon oxynitride (SiOₓN_{y}), aluminum nitride (AlNₓ), aluminum oxide (AlOₓ), and the like. The drawing illustrates that the insulating film 38 is formed as a single layer. However, the disclosure is not limited thereto. In embodiments, the insulating film 38 may be embodied as a multiple layer structure in which layers are stacked.

The insulating film 38 may protect the members of the light-emitting element ED. The insulating film 38 may prevent an electrical short circuit that may otherwise occur in the light-emitting layer 36 when the light-emitting element ED directly contacts an electrode to which the electrical signal is transmitted. The insulating film 38 may prevent deterioration of the luminous efficiency of the light-emitting element ED.

An outer surface of the insulating film 38 may be surface-treated. The light-emitting elements ED may be sprayed onto the electrode while being dispersed in an ink and aligned with each other. In order to prevent adjacent light-emitting elements ED from being agglomerated with each other and to keep the light-emitting elements ED in a dispersed state in the ink, a surface of the insulating film 38 may be treated to have hydrophobicity or hydrophilicity.

For manufacturing the above-described light-emitting element ED, a light-emitting element structure may be formed by sequentially forming the second semiconductor layer 32, the light-emitting layer 36, and the first semiconductor layer 31 on a sapphire substrate, and forming the first intermediate layer 37 and the electrode layer 40 on the first semiconductor layer 31. Since the light-emitting element structure formed on the sapphire substrate may be manufactured by a general light-emitting element manufacturing process or a semiconductor manufacturing process, a detailed description thereof will be omitted. The light-emitting element structure may then be removed from the sapphire substrate. In this way, the light-emitting element ED may be manufactured.

In an embodiment, in the light-emitting element ED, dopants may be doped into the first semiconductor layer 31 in order to improve the contact characteristic between the first semiconductor layer 31 and the electrode layer 40.

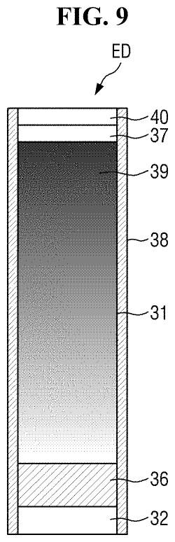

FIG. 9 is a schematic cross-sectional view showing a light-emitting element according to an embodiment.

The light-emitting element illustrated in FIG. 9 is different from the light-emitting element ED of FIG. 5 in that the first semiconductor layer 31 of the light-emitting element ED includes a dopant 39. Hereinafter, the description of the same configuration therebetween will be omitted and descriptions will be made about different configurations therebetween.

The first semiconductor layer 31 of the light-emitting element ED may include the dopant 39. The dopant 39 may include a n-type dopant which may be Si, Ge, Sn, or the like. In an embodiment, the dopant 39 may include a Group IV element. The Group IV element may be typically Si. When the first semiconductor layer 31 is doped with the n-type dopant, Ga of the first semiconductor layer 31 may be replaced with the dopant to increase the number of electrons. The increase in the number of electrons may reduce contact resistivity between the first semiconductor layer 31 and the first intermediate layer 37.

The dopants 39 may be distributed in a concentration gradient in the first semiconductor layer 31. After disposing the first semiconductor layer 31, the n-type dopant may be doped into a surface of the first semiconductor layer 31. The highest concentration of the dopant 39 may be at a surface of the first semiconductor layer 31, while the lowest concentration thereof may be at an opposite surface thereto of the first semiconductor layer 31. In an embodiment, the concentration of the dopant 39 in the first semiconductor layer 31 may increase toward the first intermediate layer 37. For example, the concentration of the dopant 39 in the first semiconductor layer 31 may decrease toward the light-emitting layer 36. When the concentration of dopant 39 is higher in region of the first semiconductor layer 31 closer to the first intermediate layer 37, the number of electrons in this area may be increased, so that a contact resistivity thereof with the first intermediate layer 37 may be reduced.

In an embodiment, the light-emitting element ED may further include a second intermediate layer to improve the contact characteristic between the first semiconductor layer 31 and the electrode layer 40.

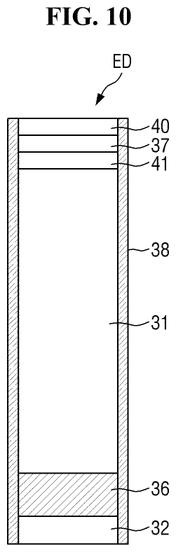

FIG. 10 is a schematic cross-sectional view showing a light-emitting element according to an embodiment.

The light-emitting element ED illustrated in FIG. 10 is different from the light-emitting element ED illustrated in each of FIG. 5 and FIG. 9 as described above in that the light-emitting element ED illustrated in FIG. 10 further includes a second intermediate layer 41 between the first intermediate layer 37 and the first semiconductor layer 31. Hereinafter, the description of the same configuration therebetween will be omitted and descriptions will be made about different configurations therebetween.

The light-emitting element ED may include the second intermediate layer 41 between the first intermediate layer 37 and the first semiconductor layer 31. The second intermediate layer 41 may be disposed between the first intermediate layer 37 and the first semiconductor layer 31 so that a surface thereof may contact the first semiconductor layer 31 and an opposite surface thereof may contact the first intermediate layer 37. Thus, the second intermediate layer 41 may include a surface that contacts the first semiconductor layer 31 and an opposite surface that contacts the first intermediate layer 37. The second intermediate layer 41 may change a polarization direction in a surface of the first semiconductor layer 31. As the first semiconductor layer 31 is grown and deposited on the substrate, a surface thereof in contact with the substrate may have a gallium (Ga) surface, and a grown surface thereof may have a nitrogen (N) surface. The gallium surface may have a +C plate characteristic and the nitrogen surface may have a −C plate characteristic, so that polarization directions thereof may be opposite to each other. The polarization directions opposite to each other may reduce the contact characteristic between the first intermediate layer 37 and the first semiconductor layer 31. Therefore, placing the second intermediate layer 41 having a polarization direction opposite to a polarization direction of the −C plate of the nitrogen surface between the first semiconductor layer 31 and the first intermediate layer 37 may allow improvement of the contact characteristic between the first semiconductor layer 31 and the first intermediate layer 37.

The second intermediate layer 41 may include a metal nitride. The metal nitride of the second intermediate layer 41 and the first intermediate layer 37 may include a same metal. For example, the metal of the metal nitride may include one selected from a group consisting of indium (In), tin (Sn), titanium (Ti), aluminum (Al), chromium (Cr), silver (Ag), gold (Au), palladium (Pd), nickel (Ni), tungsten (W), iridium (Ir), platinum (Pt), cobalt (Co), copper (Cu), ruthenium (Ru), rhodium (Rh), rubidium (Rb), lanthanum (La), cerium (Ce), sodium (Na), and europium (Eu). In an embodiment, the first intermediate layer 37 may be made of indium and the second intermediate layer 41 may be made of indium nitride. However, the disclosure is not limited thereto.

The second intermediate layer 41 may have a thickness within a range that does not degrade the transmittance of light. In an embodiment, a thickness of the second intermediate layer 41 may be in a range of about 1 nm to about 30 nm. Because the transmittance depends on a type of the metal included in the second intermediate layer 41, the thickness of the second intermediate layer 41 may be related to a thickness of the first intermediate layer 37. For example, when the transmittance of a light-emitting element ED including a first intermediate layer 37 made of indium is equal to or greater than about 70%, a thickness of a second intermediate layer 41 made of indium nitride may be sized to maintain the transmittance equal to or greater than about 70% of the light-emitting element ED. The thicknesses of each of the first intermediate layer 37 and the second intermediate layer 41 may be adjusted within a range in which a sum of the thicknesses of the first intermediate layer 37 and the second intermediate layer 41 is equal to or less than about 30 nm.

In an embodiment, in the light-emitting element ED, the electrode layer 40 may include a metal which may reflect light.

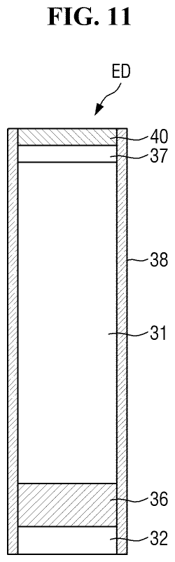

FIG. 11 is a schematic cross-sectional view showing a light-emitting element according to an embodiment.

The light-emitting element illustrated in FIG. 11 is different from the light-emitting element ED illustrated in each of FIG. 5, FIG. 9, and FIG. 10 in that the electrode layer 40 of the light-emitting element ED illustrated in FIG. 11 includes a metal that may reflect light. Hereinafter, the description of the same configuration therebetween will be omitted and descriptions will be made about different configurations therebetween.

The electrode layer 40 of the light-emitting element ED may include the metal to reflect light therefrom. The light-emitting element ED of each of the above mentioned embodiments may include the electrode layer 40 as a transparent electrode, so that the light from the light-emitting layer 36 may emit through the electrode layer 40. In the light-emitting element ED illustrated in FIG. 11, forming the electrode layer 40 as a reflective electrode that reflects light therefrom may allow the light from the light-emitting layer 36 to emit in a direction perpendicular to the length direction of the light-emitting element ED.

The electrode layer 40 may be a reflective electrode and may include a metal capable of reflecting light. For example, the electrode layer 40 and the first intermediate layer 37 may include a same material. The electrode layer 40 may include at least one selected from a group consisting of indium (In), tin (Sn), titanium (Ti), aluminum (Al), chromium (Cr), silver (Ag), gold (Au), palladium (Pd), nickel (Ni), tungsten (W), iridium (Ir), platinum (Pt), cobalt (Co), copper (Cu), ruthenium (Ru), rhodium (Rh), rubidium (Rb), lanthanum (La), cerium (Ce), sodium (Na), and europium (Eu). The electrode layer 40 may be composed of a single layer or a multi-layer made of the aforementioned metal.

Hereinafter, embodiments of the disclosure will be described based on Manufacturing Examples and Experimental Examples. However, the disclosure is not limited thereto.

### Manufacturing Example 1: Manufacturing of Light-Emitting Element Having First Intermediate Layer Made of Tin

A light-emitting element sample #1 was manufactured by sequentially growing a p-GaN layer, a light-emitting layer, and an n-GaN layer on a substrate, and forming an electrode layer which was 150 nm thick and was made of ITO on the n-GaN layer. A light-emitting element sample #2 was manufactured by forming an electrode layer having a two-layer structure of a titanium layer/an aluminum layer instead of the electrode layer made of ITO under a same process condition as that of the light-emitting element sample #1. Under a same process condition as that of the light-emitting element sample #1, a tin (Sn) layer was formed between the n-GaN layer and the ITO layer so as to have a thickness of 3 nm to form a first intermediate layer to manufacture a light-emitting element sample #3. Under a same process condition as that of the light-emitting element sample #1, a tin layer was formed to have a thickness of 10 nm to form a first intermediate layer. Thus, a light-emitting element sample #4 was manufactured. The light-emitting element samples were evaluated using a TLM (transmission line measurement) process.

### Experimental Example 1: Measurement of Current and Contact Resistivity Based on Operation Voltage of Each of Light-Emitting Element Samples

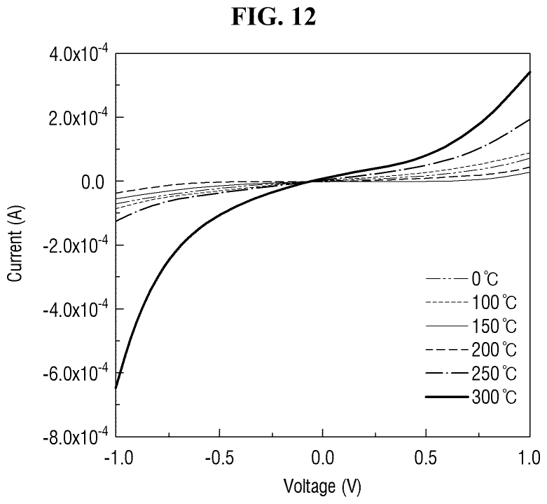

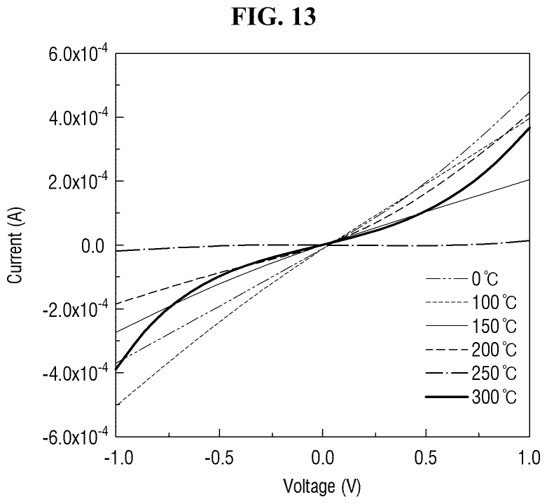

After heat-treatments at 0 degree C., 100 degrees C., 150 degrees C., 200 degrees C., 250 degrees and 300 degrees C. were performed on each of the light-emitting element samples #3 and #4 for 3 minutes, a current of each of the light-emitting element samples was measured based on an operation voltage. Results are shown in FIG. 12 and FIG. 13. The notation of 0 degree means that no heat-treatment was performed.

FIG. 12 is a graph showing a current based on an operation voltage of the light-emitting element sample #3 according to Experimental Example 1. FIG. 13 is a graph showing a current based on an operation voltage of the light-emitting element sample #4 according to Experimental Example 1.

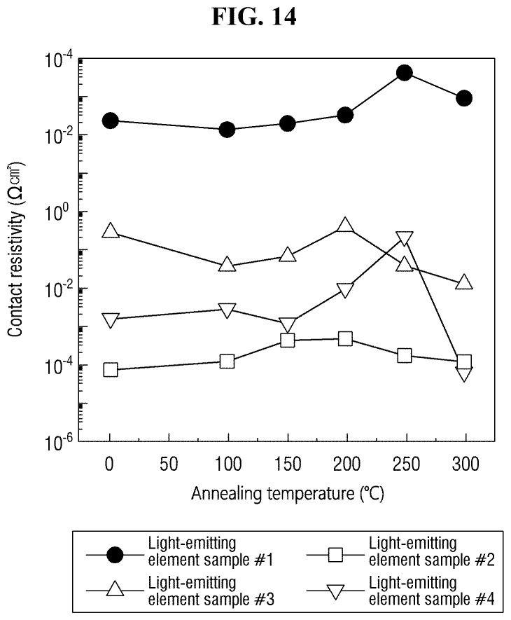

Each of light-emitting element samples #1 and #2 was subjected to heat-treatment at each of 0 degree C., 100 degrees C., 150 degrees C., 200 degrees C., 250 degrees C., and 300 degrees C. for 3 minutes. Contact resistivity of each of the light-emitting element samples #1, #2, #3 and #4 subjected to the heat-treatment was measured based on the heat-treatment temperature. Results are shown in FIG. 14.

FIG. 14 is a graph showing a contact resistivity based on a heat-treatment temperature of each of light-emitting element samples #1, #2, #3 and #4 according to Experimental Example 1.

Referring to FIG. 12 and FIG. 13, the light-emitting element sample #3 in which the tin layer having a thickness of 3 nm was formed as the first intermediate layer did not exhibit ohmic contact characteristic at each heat-treatment temperature, but exhibited Schottky contact characteristic at each heat-treatment temperature. The light-emitting element sample #3 in which the tin layer of a 10 nm thickness was formed as the first intermediate layer exhibited ohmic contact characteristic when the heat-treatment at 200 degrees C. or lower was performed thereon.

Referring to FIG. 14, the light-emitting element sample #1 in which the first intermediate layer was not formed and the ITO layer was formed as the electrode layer exhibited a contact resistivity equal to or greater than about 10² Ωcm². The light-emitting element sample #2 in which a stack of a titanium/an aluminum layer was formed as the electrode layer and the first intermediate layer was not formed exhibited a contact resistivity of about 10⁻⁴ Ωcm². The light-emitting element sample #3 in which the first intermediate layer was 3 nm thick and was made of tin and the electrode layer was made of ITO exhibited a contact resistivity equal to or greater than about 10⁻² Ωcm². The light-emitting element sample #4 in which the first intermediate layer was 10 nm thick and was made of tin and the electrode layer was made of ITO exhibited a contact resistivity of about 10⁻³ Ωcm².

It was identified based on the above results that in the light-emitting element having the electrode layer as the ITO layer, ohmic contact may be achieved between the n-GaN layer and the ITO layer when the first intermediate layer was made of tin and had a thickness of an embodiment.

### Manufacturing Example 2: Manufacturing of Light-Emitting Element Including First Intermediate Layer Made of Titanium

Under a same process condition as that of the light-emitting element sample #1, a titanium layer was formed between the n-GaN layer and the ITO layer so as to have a thickness of 3 nm to form the first intermediate layer to manufacture a light-emitting element sample #5. Under a same process condition as that of the light-emitting element samples #1, a titanium layer was formed to have a thickness of 10 nm to form the first intermediate layer. Thus, a light-emitting element samples #6 was manufactured.

### Experimental Example 2: Measurement of Current and Contact Resistivity Based on Operation Voltage of Each of Light-Emitting Element Samples

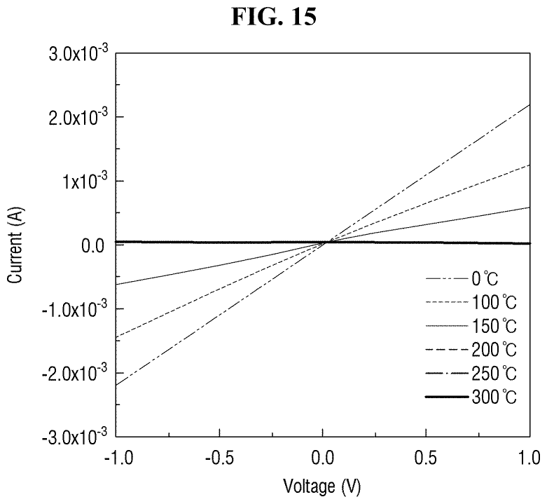

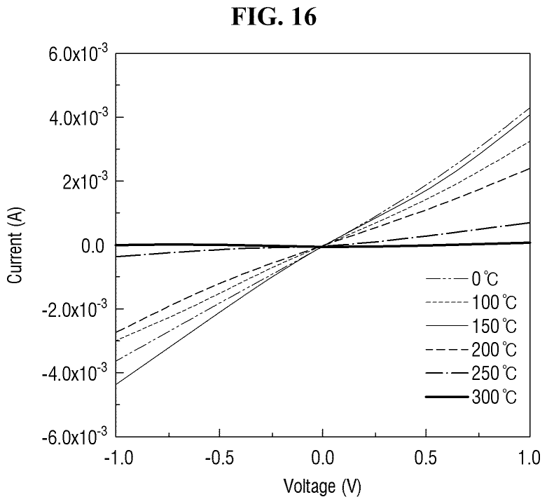

After heat-treatment at each of 0 degree C., 100 degrees C., 150 degrees C., 200 degrees C., 250 degrees and 300 degrees C. was performed on each of the light-emitting element samples #5 and #6 for 3 minutes, a current of each of the light-emitting element samples was measured based on an operation voltage. Results are shown in FIG. 15 and FIG. 16.

FIG. 15 is a graph showing a current based on an operation voltage of the light-emitting element sample #5 according to Experimental Example 2. FIG. 16 is a graph showing a current based on an operation voltage of the light-emitting element sample #6 according to Experimental Example 2.

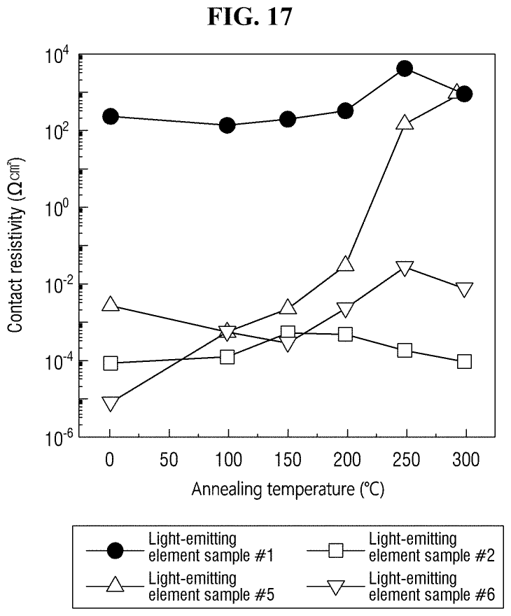

Contact resistivity based on the heat-treatment temperature of each of the light-emitting element samples #1 and #2 that were heat-treated in Experimental Example 1, and contact resistivity based on the heat-treatment temperature of each of the light-emitting element samples #5 and #6 that were heat-treated in Experimental Example 2 were measured. Results are shown in FIG. 17.

FIG. 17 is a graph showing a contact resistivity based on a heat-treatment temperature of each of the light-emitting element samples #1, #2, #5 and #6 according to Experimental Example 2.

Referring to FIG. 15 and FIG. 16, the light-emitting element sample #5 in which the titanium layer having a 3 nm was formed as the first intermediate layer exhibited ohmic contact characteristics when the heat-treatment of 200 degrees C. or lower was performed thereon. The light-emitting element sample #6 in which the titanium layer having a 10 nm thickness was formed as the first intermediate layer exhibited ohmic contact characteristic when the heat-treatment at 200 degrees C. or lower was performed thereon.

Referring to FIG. 17, the light-emitting element sample #5 in which the first intermediate layer was 3 nm thick and was made of titanium and the electrode layer was made of ITO had a contact resistivity equal to or less than about 10⁻² Ωcm² when heat-treatment at 200 degrees C. or lower was performed thereon.

The light-emitting element sample #6 in which the first intermediate layer was 10 nm thick and was made of titanium and the electrode layer was made of ITO had a contact resistivity of about 10⁻³ Ωcm² or lower when heat-treatment at 200 degrees C. or lower was performed thereon.

It was identified based the above results that when the titanium layer was formed as the first intermediate layer in the light-emitting element having the electrode layer made of ITO, an ohmic contact was achieved between the n-GaN layer and the ITO layer when the heat-treatment at a temperature below a temperature of an embodiment was performed. The light-emitting element sample #6 exhibited the lowest contact resistivity when the heat-treatment was absent.

### Manufacturing Example 3: Manufacturing of Light-Emitting Element Including First Intermediate Layer Made of Indium

Under a same process condition as that of the light-emitting element sample #1, an indium layer was formed between the n-GaN layer and the ITO layer so as to have a thickness of 3 nm to form the first intermediate layer to manufacture a light-emitting element sample #7. Under a same process condition as that of the light-emitting element sample #1, an indium layer was formed to have a thickness of 10 nm to form the first intermediate layer. Thus, a light-emitting element samples #8 was manufactured.

### Experimental Example 3: Measurement of Current and Contact Resistivity Based on Operation Voltage of Each of Light-Emitting Element Samples

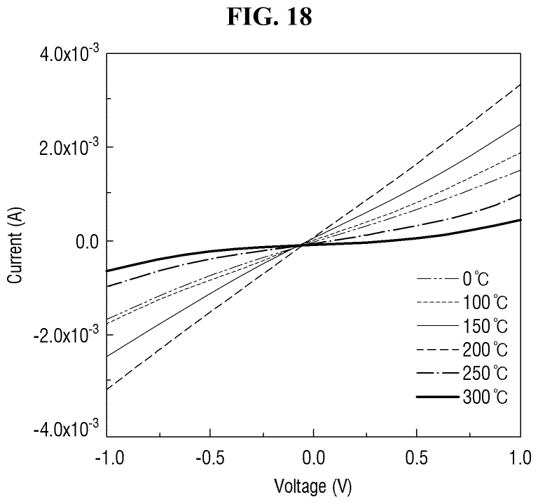

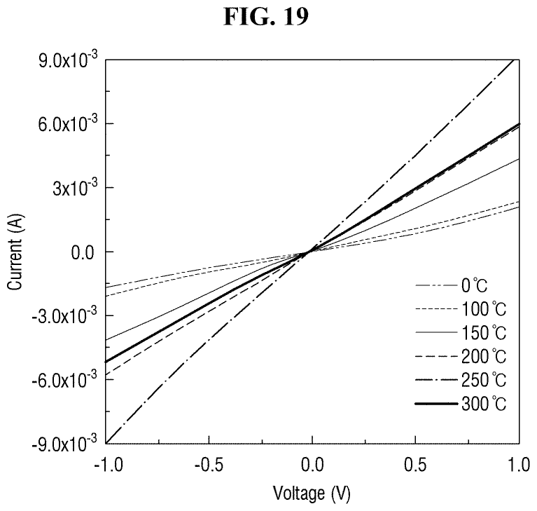

After heat-treatment at each of 0 degree C., 100 degrees C., 180 degrees C., 200 degrees C., 250 degrees and 300 degrees C. was performed on each of the light-emitting element samples #7 and #8 for 3 minutes, a current of each of the light-emitting element samples was measured based on an operation voltage. Results are shown in FIG. 18 and FIG. 19.

FIG. 18 is a graph showing a current based on an operation voltage of the light-emitting element sample #7 according to Experimental Example 3. FIG. 19 is a graph showing a current based on an operation voltage of the light-emitting element sample #8 according to Experimental Example 3.

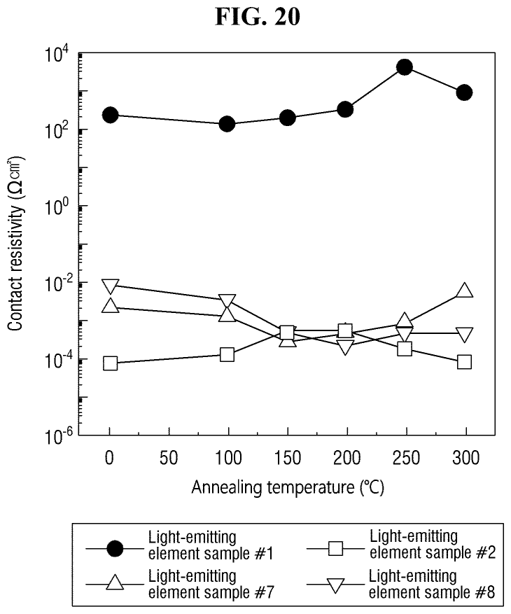

The contact resistivity based on the heat-treatment temperature of each of light-emitting element samples #1 and #2 that were heat-treated in Experimental Example 1, and the contact resistivity based on the heat-treatment temperature of each of light-emitting element samples #7 and #8 that were heat-treated in Experimental Example 3 were measured. Results are shown in FIG. 20.

FIG. 20 is a graph showing a contact resistivity based on a heat-treatment temperature of each of the light-emitting element samples #1, #2, #7 and #8 according to Experimental Example 2.

Referring to FIG. 18 and FIG. 19, the light-emitting element sample #7 in which the indium layer having a 3 nm thickness was formed as the first intermediate layer exhibited ohmic contact characteristics when the heat-treatment of 250 degrees C. or lower was performed thereon. The light-emitting element sample #8 in which the indium layer having a 10 nm thickness was formed as the first intermediate layer exhibited ohmic contact characteristic when the heat-treatment at 100 degrees C. or higher was performed thereon.

Referring to FIG. 20, the light-emitting element sample #7 in which the first intermediate layer was 3 nm thick and was made of indium and the electrode layer was made of ITO had a contact resistivity of about 10⁻³Ωcm² at all heat-treatment temperatures. The light-emitting element sample #8 in which the first intermediate layer was 10 nm thick and was made of indium and the electrode layer was made of ITO had a contact resistivity in a range of about 10⁻² Ωcm² to about 10⁻³ Ωcm² at all heat-treatment temperatures.

It was identified based the above results that when the indium layer was formed as the first intermediate layer in the light-emitting element having the electrode layer made of ITO, an ohmic contact was achieved between the n-GaN layer and the ITO layer when the heat-treatment in a temperature range of an embodiment was performed. The light-emitting element sample #8 exhibited the lowest contact resistivity.

Simulation of transmittance based on thickness of each of first intermediate layer and electrode layer

When the n-GaN layer, the first intermediate layer, and the electrode layer made of ITO were stacked on the substrate, transmittance was simulated under a condition that a thickness of the first intermediate layer varied from 0 nm to 50 nm and a thickness of the electrode layer varied from 0 nm to 300 nm. In this simulation, a material of the first intermediate layer was selected between titanium, indium, and tin. A wavelength of the transmitting light was 460 nm. A simulation tool employed Macleod simulation.

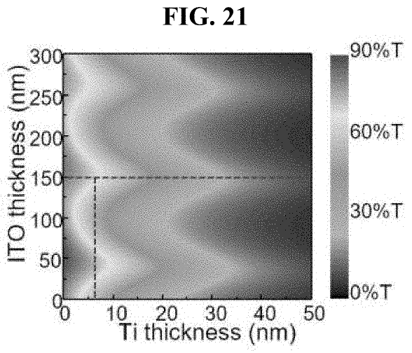

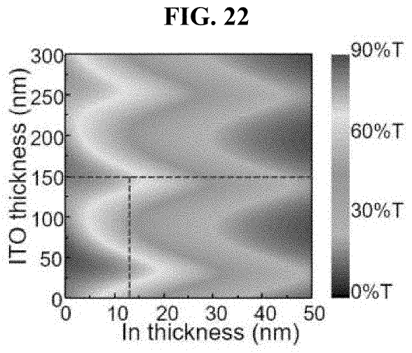

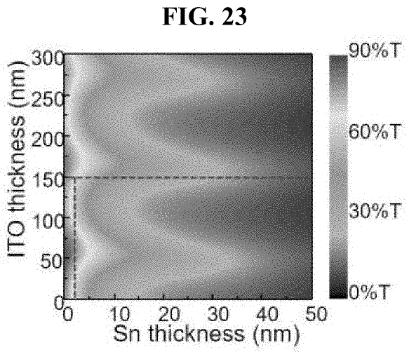

FIG. 21 is a graph showing a transmittance based on a thickness of the first intermediate layer made of titanium and a thickness of the electrode layer made of ITO. FIG. 22 is a graph showing a transmittance based on a thickness of the first intermediate layer of indium and a thickness of the electrode layer made of ITO. FIG. 23 is a graph showing a transmittance based on a thickness of the first intermediate layer made of tin and a thickness of the electrode layer made of ITO.

Referring to FIG. 21, when a thickness of the ITO layer was 150 nm or smaller and the thickness of the first intermediate layer made of titanium was 6 nm or smaller, the transmittance was equal to or greater than about 70%. Referring to FIG. 22, when a thickness of the ITO layer was 150 nm or smaller and the thickness of the first intermediate layer made of indium was 13 nm or smaller, the transmittance was equal to or greater than about 70%. Referring to FIG. 23, when a thickness of the first intermediate layer made of tin was 2 nm or smaller, and a thickness of the ITO layer was 150 nm or smaller, the transmittance was equal to or greater than about 70%.

Thus, it was identified based on the above results that the transmittance was equal to or greater than about 70% when a thickness of the first intermediate layer was equal to or less than a thickness range of an embodiment.

To verify the simulation results, following Manufacturing Example and Experimental Example were performed.

### Manufacturing Example 4: Manufacturing of Substrate Samples for Transmittance Measurement

A sapphire substrate made of aluminum oxide was prepared. Thus, a substrate sample #1 was prepared. A substrate sample #2 was manufactured by laminating the ITO layer of a thickness of 150 nm on the substrate sample #1. A titanium layer was formed to have a thickness of 3 nm as the first intermediate layer between the substrate and the ITO layer of the substrate sample #2. Thus, a substrate sample #3 was manufactured. A titanium layer was formed to have a thickness of 10 nm as the first intermediate layer between the substrate and the ITO layer of the substrate sample #2. Thus, a substrate sample #4 was manufactured. An indium layer was formed to have a thickness of 3 nm as the first intermediate layer between the substrate and the ITO layer of the substrate sample #2. Thus, a substrate sample #5 was manufactured. An indium layer was formed to have a thickness of 10 nm as the first intermediate layer between the substrate and the ITO layer of the substrate sample #2. Thus, a substrate sample #6 was manufactured. A tin layer was formed to have a thickness of 3 nm as the first intermediate layer between the substrate and the ITO layer of the substrate sample #2. Thus, a substrate sample #7 was manufactured. A tin layer was formed to have a thickness of 10 nm as the first intermediate layer between the substrate and the ITO layer of the substrate sample #2. Thus, a substrate sample #8 was manufactured.

### Experimental Example 4: Measurement of Average Transmittance Based on Heat-Treatment Temperature of Each Of Substrate Samples

Heat-treatment at each of 0 degree C., 50 degrees C., 100 degrees C., 150 degrees C., 200 degrees C., 250 degrees C., and 300 degrees C. was carried out for 3 minutes on each of the manufactured substrate samples #1, #2, #3, #4, #5, #6, #7 and #8. The transmittance of each of the substrate samples was measured. Each of the substrate samples #1, #2, #3, #4, #5, #6, #7 and #8 was prepared as substrate samples. Thus, an average transmittance thereof was measured. A wavelength range of light used for the transmittance measurement was 400 nm to 500 nm.

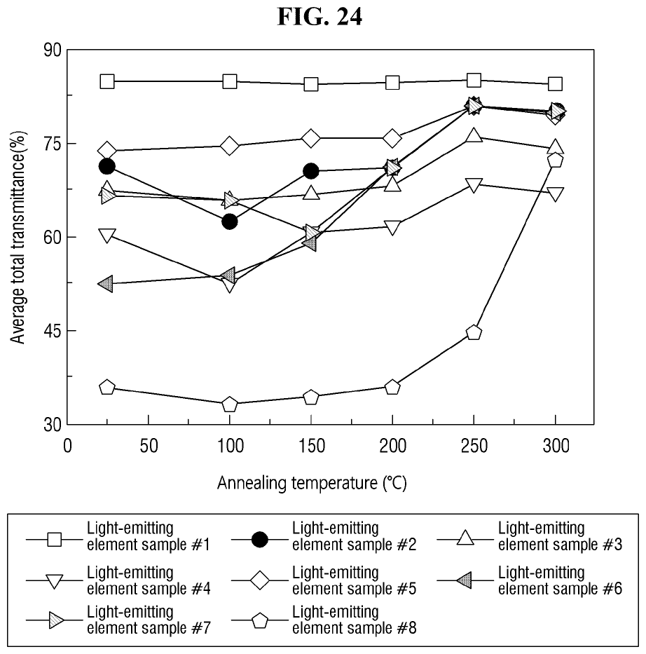

FIG. 24 is a graph showing an average transmittance of each of the substrate samples based on a heat-treatment temperature according to Experimental Example 4.

Referring to FIG. 24, the substrate sample #1 always exhibited a transmittance equal to or greater than about 80% at each of the heat-treatment temperatures. Each of the substrate samples #2 to #8 exhibited a tendency to have increase in the transmittance as the heat-treatment temperature increased. All thereof exhibited a transmittance equal to or greater than about 70%.

Thus, it was identified based on the above simulation results that the element including the first intermediate layer exhibited a transmittance equal to or greater than about 70%.

Table 1 shows contact resistivity and average transmittance based on the heat-treatment temperature of each of the electrode layer formed on the sapphire substrate, and combinations of the electrode layer and the first intermediate layer having different thicknesses and materials. In Table 1, Ti/Al means that titanium is laminated on a sapphire substrate, and aluminum is laminated on titanium. ITO means that ITO is laminated on the sapphire substrate. Ti/ITO means that titanium is laminated on the sapphire substrate, and ITO is laminated on titanium. In/ITO means that indium is laminated on the sapphire substrate, and ITO is laminated on indium. A numerical value in the parentheses indicates a thickness. The average transmittance is about light in a 400 nm to 500 nm wavelength band.

TABLE 1

| | Heat-treatment | Contact | Average |
|---|---|---|---|
| | temperature (° C.) | resistivity (Ωcm²) | transmittance (%) |
| Ti/A1 | — | 7.81 × 10⁻⁵ | 0 |
| ITO | — | 2.08 × 10² | 71.4 |
| Ti(10 nm)/ITO | — | 6.63 × 10⁻⁶ | 60.5 |
| In(3 nm)/ITO | 150 | 3.29 × 10⁻⁴ | 75.7 |
| | 200 | 4.05 × 10⁻⁴ | 75.9 |
| | 250 | 7.44 × 10⁻⁴ | 80.9 |
| In(10 nm)/ITO | 200 | 2.20 × 10⁻⁴ | 71.6 |
| | 250 | 4.32 × 10⁻⁴ | 81.2 |

Referring to the Table 1, when titanium or indium was used as the material of the first intermediate layer, and ITO was used as the material of the electrode layer, the contact resistivity was equal to or less than about 10⁻³ Ωcm², thereby satisfying required electrical characteristics. Transmittance was generally equal to or greater than about 70%. Thus, a required optical characteristic was also satisfied.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first semiconductor layer doped with an n-type dopant;
a second semiconductor layer disposed below the first semiconductor layer and doped with a p-type dopant;
a light-emitting layer disposed between the first semiconductor layer and the second semiconductor layer;
a first intermediate layer disposed on the first semiconductor layer, and including a metal; and
an electrode layer disposed on the first intermediate layer, wherein
light from the light-emitting layer transmits through the first semiconductor layer, the first intermediate layer, and the electrode layer at a transmittance equal to or greater than about 70%.

2. The light-emitting element of claim 1, wherein the first intermediate layer includes at least one selected from a group consisting of indium (In), tin (Sn), titanium (Ti), aluminum (Al), chromium (Cr), silver (Ag), gold (Au), palladium (Pd), nickel (Ni), tungsten (W), iridium (Ir), platinum (Pt), cobalt (Co), copper (Cu), ruthenium (Ru), rhodium (Rh), rubidium (Rb), lanthanum (La), cerium (Ce), sodium (Na), and europium (Eu).

3. The light-emitting element of claim 1, wherein the first intermediate layer includes:
a surface that contacts the first semiconductor layer; and
an opposite surface that contacts the first intermediate layer.

4. The light-emitting element of claim 1, wherein the first intermediate layer has a work function that is between a work function of the first semiconductor layer and a work function of the electrode layer.

5. The light-emitting element of claim 1, wherein a thickness of the first intermediate layer is in a range of about 1 nm to about 30 nm.

6. The light-emitting element of claim 1, wherein
the electrode layer includes a metal oxide, and
the metal oxide includes at least one selected from a group consisting of ITO (indium tin oxide), AlZO (aluminum zinc oxide), IZO (indium zinc oxide), ZnO (zinc oxide), InₓO_{y} (indium oxide), SnₓO_{y} (tin oxide), AlOₓ (aluminum oxide) and GaₓO_{y} (gallium oxide).

7. The light-emitting element of claim 6, wherein the electrode layer and the first intermediate layer include a same material.

8. The light-emitting element of claim 1, wherein the n-type dopant of the first semiconductor layer has a concentration gradient where a concentration of the n-type dopant increases toward the first intermediate layer.

9. The light-emitting element of claim 1, further comprising a second intermediate layer disposed between the first semiconductor layer and the first intermediate layer,
wherein the second intermediate layer includes:
a surface that contacts the first semiconductor layer; and
an opposite surface that contacts the first intermediate layer.

10. The light-emitting element of claim 9, wherein
the second intermediate layer includes a metal nitride, and
a metal of the metal nitride includes at least one selected from a group consisting of indium (In), tin (Sn), titanium (Ti), aluminum (Al), chromium (Cr), silver (Ag), gold (Au), palladium (Pd), nickel (Ni), tungsten (W), iridium (Ir), platinum (Pt), cobalt (Co), copper (Cu), ruthenium (Ru), rhodium (Rh), rubidium (Rb), lanthanum (La), cerium (Ce), sodium (Na), and europium (Eu).

11. The light-emitting element of claim 1, wherein a contact resistivity of the light-emitting device is equal to or less than about 10⁻³ Ωcm².

12. The light-emitting element of claim 1, further comprising an insulating film that surrounds the first semiconductor layer, the second semiconductor layer, the light-emitting layer, the first intermediate layer, and the electrode layer.

13. A display device comprising:
a first electrode and a second electrode each disposed on a substrate and spaced apart from each other;
a first insulating layer disposed on the first electrode and the second electrode;
light-emitting elements disposed on the first insulating layer and vertically overlapping the first electrode and the second electrode;
a first connection electrode that contacts an end of each light-emitting elements; and
a second connection electrode that contacts an opposite end of each light-emitting elements, wherein
each of the light-emitting elements includes:
a first semiconductor layer doped with an n-type dopant;
a second semiconductor layer disposed below the first semiconductor layer and doped with a p-type dopant;
a light-emitting layer disposed between the first semiconductor layer and the second semiconductor layer;
a first intermediate layer disposed on the first semiconductor layer, and including a metal; and
an electrode layer disposed on the first intermediate layer,
light from the light-emitting layer transmits through the first semiconductor layer, the first intermediate layer, and the electrode layer at a transmittance equal to or greater than about 70%,
the second semiconductor layer contacts the first connection electrode, and
the electrode layer contacts the second connection electrode.

14. The device of claim 13, wherein a thickness of the first intermediate layer is in a range of about 1 nm to about 30 nm.

15. The device of claim 13, wherein the first intermediate layer includes:
a surface that contacts the first semiconductor layer; and
an opposite surface that contacts the first intermediate layer.

16. The device of claim 13, wherein the first intermediate layer has a work function that is between a work function of the first semiconductor layer and a work function of the electrode layer.

17. The device of claim 13, wherein the n-type dopant of the first semiconductor layer has a concentration gradient in which a concentration of the n-type dopant increases toward the first intermediate layer.

18. The device of claim 13, wherein
each light-emitting element further includes a second intermediate layer disposed between the first semiconductor layer and the first intermediate layer, and
the second intermediate layer includes:
a surface that contacts the first semiconductor layer, and
an opposite surface that contacts the first intermediate layer.

19. The device of claim 18, wherein
the second intermediate layer includes a metal nitride, and
the metal nitride of the second intermediate layer and the first intermediate layer include a same metal.

20. The device of claim 13, wherein a contact resistivity of each light-emitting element is equal to or less than about 10⁻³ Ωcm².
